(19) United States
(12) Patent Application Publication
(10) Pub. No.: US 2006/0154479 A1
(43) Pub. Date: Jul. 13, 2006

(54) Baking apparatus used in photolithography process, and method for controlling critical dimension of photoresist patterns using the same

(75) Inventor: Dong Jin Lee, Bucheon-si (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/318,508

(22) Filed: Dec. 28, 2005

(30) Foreign Application Priority Data
Dec. 28, 2004 (KR) 10-2004-0114489

(51) Int. Cl. H01L 21/44; H01L 21/302; H01L 21/31; H01L 21/461; H01L 21/469

(52) U.S. Cl. 438/660; 438/689; 438/780

(57) ABSTRACT

A baking apparatus used in a photolithography process of a semiconductor device, and a method for controlling critical dimension of a photoresist pattern using the same. The baking apparatus comprises: a processing chamber; a chuck disposed in the processing chamber on which a semiconductor wafer can be loaded; and a heating means supplying a different temperature of heat by regions of the wafer.

This application claims the benefit of Korean Application No. 10-2004-0114489, filed on Dec. 28, 2004, which is incorporated by reference herein in its entirety.

### BACKGROUND OF THE INVENTION

1. Field of the Invention

The present invention generally relates to the semiconductor device manufacturing technology. More specifically, the present invention relates to a baking apparatus used in a photolithography process, and a method for controlling critical dimensions of a photoresist pattern using the same.

2. Description of the Related Art

In general, highly integrated semiconductor devices involve miniaturized circuit patterns of which formation requires the rigorous management of processing parameters. In particular, operating parameters of a photolithography process may directly influence the size of the miniaturized patterns.

The photolithography process for defining the miniaturized patterns generally comprises the steps of: applying a photoresist on a semiconductor wafer; exposing the applied photoresist layer to light through a reticle to transcribe a pattern of the reticle onto the photoresist layer; and developing the exposed photoresist layer to form a photoresist pattern. In addition, the photolithography process can further include baking steps before and after the exposure step. The bake before the exposure step, generally known as a pre-bake, vaporizes solvents in the photoresist layer to improve the adherence of the photoresist to the wafer. The bake after the exposure step, generally known as a post-bake or hard-bake, hardens the exposed photoresist layer.

After the post-baking step, the photoresist layer is developed, and the exposed portions of the photoresist layer are then removed (i.e., in case of a positive photoresist) to form the photoresist pattern.

In such photolithography process, even though the entire region of the wafer undergoes the uniform or fixed condition of exposure process, critical dimensions of the photoresist patterns may differ according to their locations in the wafer. In addition, various kinds of underlying layers below the photoresist layer, e.g., dielectrics, metal layers, etc., may be formed in different thicknesses by so-called loading effects, which leads to difference of critical dimensions between the photoresist patterns. It is believed that the focus of exposing light may differ according to the thickness of the underlying layer below the photoresist layer. Moreover, the photoresist patterns may undergo discoloration during cleaning processes. Such change of a photoresist's color may also result in a difference of critical dimensions between the photoresist patterns.

As a consequence of the difference in critical dimensions, the yield of semiconductor devices from the wafer may be deteriorated. One approach to minimize the difference in critical dimensions of the photoresist patterns is to expose the photoresist layer in different conditions according to the location of the wafer. However, it may be accompanied by complicated recipes, thus resulting in decrease of productivity of the devices.

### SUMMARY OF THE INVENTION

It is, therefore, an object of the present invention to provide a baking apparatus used in a photolithography process of a semiconductor device, in which a photoresist layer can be baked at different temperatures for regions of a semiconductor wafer.

Another object of the present invention is to provide a method for controlling critical dimensions of photoresist patterns using the baking apparatus, wherein the photoresist patterns can be formed with a fixed and desired critical dimension.

To achieve the above objects, an embodiment of a baking apparatus used in a photolithography process, according to the present invention, comprises: a processing chamber; a chuck disposed in the processing chamber on which a semiconductor wafer can be loaded; and a heating means supplying a different temperature for different regions of the wafer.

Preferably, the heating means comprises a plurality of heating elements, such as heating coils installed in the chuck, or a plurality of warm air tubes installed on the inside wall of the processing chamber.

In addition, a method for controlling a critical dimension of a photoresist pattern in a photolithography process of a semiconductor device, according to the present invention, comprises: exposing a photoresist layer applied on a semiconductor wafer in a fixed condition on an entire region of the wafer; and baking the photoresist layer at different temperatures for different regions of the wafer.

Preferably, a first region of the wafer is heated at a temperature higher than a second region of the wafer, when the first region has a relatively high critical dimension in a normal photolithography process, and the second region has a relatively low critical dimension in the normal photolithography process.

It is to be understood that both the foregoing general description of the invention and the following detailed description are exemplary, but are not restrictive of the invention.

### BRIEF DESCRIPTION OF DRAWINGS

These and other aspects of the present invention will become evident by reference to the following description of the invention, often referring to the accompanying drawings.

FIG. 1 is a cross-sectional view of an embodiment of a baking apparatus according to the present invention.

FIG. 2 is a cross-sectional view of another embodiment of a baking apparatus according to the present invention.

FIG. 3 is a flow chart, illustrating a method for controlling a critical dimension of a photoresist pattern in a photolithography process of a semiconductor device, according to the present invention.

### DETAILED DESCRIPTION OF THE INVENTION

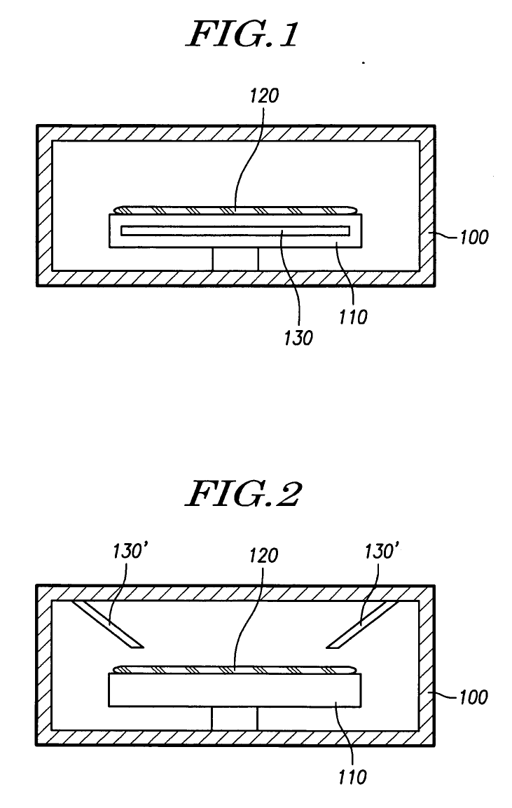

FIG. 1 is a cross-sectional view of an embodiment of a baking apparatus, according to the present invention.

Referring to FIG. 1, the baking apparatus comprises a processing chamber 100 in which a baking process of a semiconductor wafer 120 can be performed. A chuck 110, on which the wafer 120 is loaded, is disposed in the processing chamber 100.

The baking apparatus further comprises heating means 130 that can apply heat to the wafer 120. In particular, the heating means 130 can include a plurality of heating elements, such as heating coils, which respectively apply a different temperature depending on a region of the wafer 120. The heating elements 130 can be installed in the chuck 110.

Each region of the wafer 120 can be heated at a different temperature by the heating means 130 including the plurality of heating elements during the post-baking process.

Another embodiment of a baking apparatus for applying a different temperature of heat depending regions of the wafer is described, with reference to FIG. 2.

Referring to FIG. 2, the processing chamber 100 comprises a different type of heating means 130′ from the heating elements 130 in FIG. 1. The heating means 130′ can include a plurality of warm air tubes that are installed on the inside wall of the processing chamber 100. Each of the plurality of warm air tubes is directed at a predetermined region of the wafer. Each of warm air tubes is movable to apply a different temperature of warm air onto a selected region of the wafer 120. Namely, each region of the wafer 120 can be heated at a different temperature by the warm air supplied from the tubes 130′.

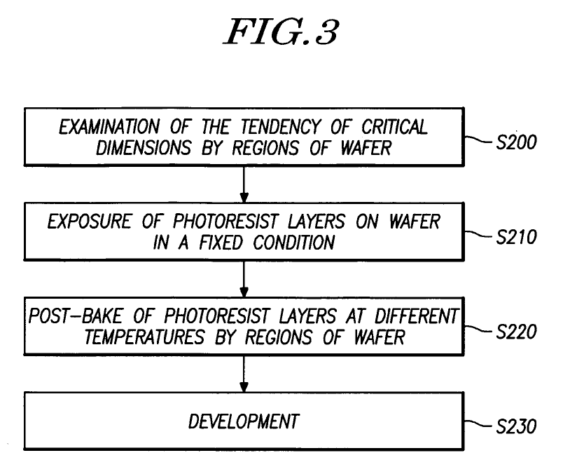

Next, a method for controlling critical dimensions of photoresist patterns using the aforementioned baking apparatuses, according to the present invention, is described hereinafter, with reference to FIG. 3.

FIG. 3 is a processing flow chart of the critical dimension controlling method. First, a plurality of wafers is processed according to a normal photolithography process. From the measurement of electrical characteristics of the photolithographic processed wafers, the characteristics of the critical dimensions of the photoresist patterns by regions of the wafer are examined (S200). For instance, in case of the photolithography process for forming a photoresist pattern defining a channel width of a gate electrode of MOS (metal oxide semiconductor) transistor, its critical dimension can be calculated by measurement of turn-on current of the completed MOS transistor. This type of electrical test can be performed periodically on the manufactured MOS transistors.

Subsequently, according to the photolithography process in which the characteristics of the critical dimension of the photoresist pattern are examined, a processing wafer undergoes the exposure step (S210) in such fixed condition as before the examination of the characteristics of the critical dimension.

After the exposure of the wafer, a post-baking step (S220) is performed in the baking apparatus according to the present invention. In this case, the wafer is heated at different temperatures, according to regions of the wafer (i.e., by regions). More specifically, supposing the critical dimension is decreased by about 15 millimeters (mm) with a temperature rise of about 2° C., the post-baking step would be performed at different temperatures for different regions of the wafer, based on the results of the examination of the characteristics and variations of the critical dimension according to the temperature. In other words, on the basis of the examination results in step S200, a region of a relatively high critical dimension is post-baked at a relatively high temperature, in comparison with a region of a relatively low critical dimension.

After the post-baking step, the photoresist layer is developed (S230), and the exposed portions of the photoresist layer are then removed (i.e., in case of a positive photoresist) to form the photoresist patterns having the fixed and desired critical dimensions.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A baking apparatus used in a photolithography process of a semiconductor device, comprising:
a processing chamber;
a chuck disposed in the processing chamber on which a semiconductor wafer can be loaded; and
heating means supplying a different temperature to different regions of the wafer.

2. The apparatus of claim 1, wherein the heating means comprises a plurality of heating elements installed in the chuck.

3. The apparatus of claim 1, wherein the heating means comprises a plurality of warm air tubes installed on an inside wall of the processing chamber.

4. A method for controlling a critical dimension of a photoresist pattern in a photolithography process of a semiconductor device, comprising:
exposing a photoresist layer applied on a semiconductor wafer in a fixed condition on an entire region of the wafer; and
baking the photoresist layer at different temperatures for different regions of the wafer.

5. The method of claim 4, wherein the baking includes heating a first region of the wafer at a temperature higher than a second region of the wafer, the first region having a relatively high critical dimension, and the second region having a relatively low critical dimension.

6. A baking apparatus used in a photolithography process of a semiconductor device, comprising:
a processing chamber;
a chuck disposed in the processing chamber on which a semiconductor wafer can be loaded; and
at least one heating element configured to supply a different temperature to different regions of the wafer.

7. The apparatus of claim 6, wherein the at least one heating element includes a plurality of heating elements installed in the chuck.

8. The apparatus of claim 6, wherein the at least one heating element includes a plurality of warm air tubes installed on an inside wall of the processing chamber.

9. A method for controlling a critical dimension of a photoresist pattern in a photolithography process of a semiconductor device, comprising the steps of:
a step for exposing a photoresist layer applied on a semiconductor wafer in a fixed condition on an entire region of the wafer; and
a step for baking the photoresist layer at different temperatures for different regions of the wafer.

10. The method of claim 4, wherein the step for baking includes heating a first region of the wafer at a temperature higher than a second region of the wafer, the first region having a relatively high critical dimension, and the second region having a relatively low critical dimension.
